(19) United States
(12) Patent Application Publication
(10) Pub. No.: US 2024/0425365 A1
(43) Pub. Date: Dec. 26, 2024

(54) LOW VOLTAGE CAPACITIVE MICROMACHINED ULTRASONIC TRANSDUCER (CMUT) DESIGN AND MANUFACTURING FLOW

(71) Applicant: SENSONICS TRANSDUCERS PRIVATE LIMITED, Bangalore (IN)

(72) Inventors: Brishbhan Singh PANWAR, Bangalore (IN); Rajat GUPTA, Bangalore (IN)

(21) Appl. No.: 18/693,539

(22) PCT Filed: Sep. 23, 2022
(86) PCT No.: PCT/IN2022/050851

§ 371 Date: Mar. 20, 2024

(51) Int. Cl. B81C 1/00; B81B 3/00

(52) U.S. Cl. CPC B81C 1/00698; B81B 3/0086; B81B 2203/0127; B81B 2203/0315; B81B 2203/0361; B81B 2207/11; B81C 2201/0104; B81C 2201/0132; B81C 2201/0133; B81C 2201/014; B81C 2201/0147; B81C 2201/0164; B81C 2201/0178

(57) ABSTRACT

A method for deigning a low voltage capacitive micromachined ultrasonic transducer (CMUT) is provided. The method includes starting from a base silicon wafer includes starting with a N-type Silicon Wafer and growing base oxide by patterning with a metal mask over the base oxide, patterning with a Field Oxide (FOX) Mask over a copper (Cu) or Aluminium (Al) metal (M1) layer that is deposited over the base oxide, depositing polysilicon over the entire silicon wafer and doping the polysilicon with a donor species with a concentration approaching its respective solid solubility limit and subsequently depositing titanium (Ti) over the doped polysilicon that is deposited on the entire silicon wafer and subsequently depositing a dielectric layer. The dielectric layer is standalone Silicon Dioxide or in a stack with Hafnium Oxide or alternatively in a stack with Silicon Nitride or a suitable stack of high relative permittivity materials.

### CROSS-REFERENCE TO RELATED APPLICATIONS

This application claims priority to the Indian provisional patent application no. 202141043234 filed on Sep. 23, 2021, the complete disclosures of which, in their entirety, are herein incorporated by reference.

### TECHNICAL FIELD

The embodiments herein generally relate to a capacitive micromachined ultrasonic transducer (CMUT), and more particularly, to a method of designing a low voltage capacitive micromachined ultrasonic transducer (CMUT) for complementary metal-oxide-semiconductor (CMOS).

### DESCRIPTION OF THE RELATED ART

A capacitive micromachined ultrasonic transducer (CMUT) is a relatively new concept in the field of ultrasonic transducers. Most of the commercial ultrasonic transducers today are based on piezoelectricity. CMUTs are the transducers where the energy transduction is due to a change in the stiffness coefficient of a membrane due to an electrostatic field in a vacuum enclosed by two conducting plates. CMUTs are constructed on silicon using micromachining techniques. A cavity is formed in a silicon substrate, and a thin electrically conducting layer suspended on the top of the cavity serves as a membrane on which a metalized layer acts as an electrode, together with the silicon substrate which serves as a bottom electrode.

Existing CMUTs intended for operation whether in un-collapsed or deep-collapse mode require very high operating voltages of the order of 100V. Large CMUT Arrays require a large number of interconnects largely due to difficulties in isolating the lower plate(s) of the individual CMUT elements in the array. The silicon real estate used by the array gets further increased due to the non-availability/non-usage of a different metal layer for the upper plate(s) from that used by the lower plate(s), preventing Manhattan-style crossings of interconnect lines. Existing CMUT technologies have (at least) two constraints preventing homogeneous integration to bulk CMOS Processes.

Accordingly, there remains a need for mitigating and/or overcoming drawbacks associated with current methods.

### SUMMARY

In view of the foregoing, embodiments herein provide a method for designing a low voltage capacitive micromachined ultrasonic transducer (CMUT). The method includes starting from a base silicon wafer includes starting with a N-type Silicon Wafer and growing base oxide by performing the following steps. The method includes patterning with a metal mask over the base oxide. The method includes patterning with a Field Oxide (FOX) Mask over a copper (Cu) or Aluminium (Al) metal (M1) layer that is deposited over the base oxide. The method includes depositing polysilicon over the entire silicon wafer and doping the polysilicon with a donor species with a concentration approaching its respective solid solubility limit and subsequently depositing titanium (Ti) over the doped polysilicon that is deposited on the entire silicon wafer and subsequently depositing a dielectric layer, wherein the dielectric layer is Silicon Dioxide or in a stack with Hafnium Oxide or alternatively in a stack with Silicon Nitride or a high relative permittivity material. The method includes patterning with a pedestal-poly mask over a dielectric layer that is deposited over the titanium. The method includes removing the patterned dielectric by a wet etch process and subsequently removing exposed titanium by an alternative wet etch process and sequentially excavating by reactive ion etch (RIE) all exposed polysilicon. The method includes planarizing surface of the base silicon wafer by chemical mechanical polishing (CMP), thereby preparing the base silicon wafer for eventual bonding with a separate top silicon wafer. The method includes starting with the separate top silicon wafer including a silicon “device” layer on top of buried oxide grown over a thick “handle” silicon layer and performing the following steps. The method includes depositing by sputtering an aluminium layer of suitable thickness that may be referred as Metal 2. The method includes patterning with a Metal 2 Mask and etching the Metal 2 by a wet etch process. The method includes patterning with a CMUT Cell mask and etching the silicon “device” layer by RIE to define a CMUT top plate. The method includes aligning the separate top silicon wafer and the base silicon wafer to enable the Metal 2 of the separate top silicon wafer to align with Pillar Poly of the base silicon wafer; and heating the separate top silicon wafer and the base silicon wafer after the separate top silicon wafer and the base silicon wafer are aligned to enable the Metal 2 of the separate top silicon wafer to (a) form a eutectic bonding between the polysilicon and aluminium Metal 2 layer during which a certain thickness of the Metal 2 is consumed, and (b) form a Polycide between the Polysilicon and the Titanium (Ti) alloy in parallel, wherein the Titanium present inside the cavity (i) acts as a getter when the eutectic bonding is happening between the polysilicon and aluminium, (ii) forms chemical bonds with residual Nitrogen and Oxygen, and (c) removes the residual Nitrogen and Oxygen from the cavity, thereby improving vacuum in the cavity. The method includes depositing a Polymer layer over an entire wafer. The method includes patterning with a Polymer Mask and selectively etching the Polymer to (a) isolate CMUT cells from mechanical coupling and (b) remove the polymer at bond pads.

In some embodiments, the N-Type Silicon Wafer is replaced by P-Type Silicon Wafer. In some embodiments, concentration of the N-type Silicon Wafer is 5×10¹⁵/cm³, wherein the base oxide has 0.5μ thickness.

In some embodiments, the method includes performing dry oxidation of a silicon wafer to obtain a required silicon dioxide (SiO2) thickness of the base silicon wafer, the dry oxidation is performed at 1050° C. for an appropriate time interval. The required oxide thickness is 1 μm. In some embodiments, the method includes depositing the copper (Cu) or aluminium (Al) metal (M1) layer with a required thickness over the base oxide (SiO2). In some embodiments, a thickness of the copper or Al metal 1 layer is based on a design specification of resistivity.

In some embodiments, the method includes etching the copper/Al metal using a wet etch process to create a CMUT bottom plate and a metal (M1) interconnect layer after the metal mask is patterned over the base oxide; and depositing conformally SiO2 using Plasma-Enhanced Chemical Vapor Deposition (PECVD) over an entire silicon wafer.

In some embodiments, the method includes etching the PECVD SiO2 after the Field Oxide (FOX) Mask is patterned using buffer Hydrogen Fluoride (IF) solution to obtain CMUT cavities.

In some embodiments, the method includes etching the dielectric layer using the wet etch process to expose the titanium from all areas where underlying poly is to be etched, wherein the dielectric layer is at least one of SiO2, SiO2/HfO2 sandwich or SiO2/Si3N4 sandwich.

In some embodiments, the method includes etching the Titanium by the wet-etch process where the polysilicon acts as an “etch-stop”, wherein the Titanium (Ti) is deposited over the polysilicon with a thickness of 100 nm by sputtering.

In some embodiments, the method includes excavating the polysilicon inside cavity around the pedestal and in FOX regions adjacent to pillars to prevent shorting of adjacent CMUTs.

In some embodiments, the Chemical Mechanical Polishing (CMP) is performed on the polysilicon with a thickness of 1.4 m to remove the excess dielectric on the pillar; and the titanium (Ti on pillar polysilicon and the excess height of the polysilicon to render the surface of a wafer planar.

In some embodiments, the method includes chemical mechanical polishing (CMP) of the handle silicon layer by RIE and, sequentially, a buried oxide layer by the wet etch process.

In some embodiments, the separate top silicon wafer comprises a heavily doped top n+ silicon layer that is intended to be a membrane with a thickness of 2 μm. In some embodiments, the separate top silicon wafer comprises the thick handle silicon layer that is removed by RIE and the buried oxide layer placed below with the thickness of 0.5 μm which is removed by the wet-etch process with the silicon device layer acting as etch-stop for its removal.

In some embodiments, the Metal 2 of thickness 0.8 μm is reduced to 0.4 μm during eutectic bonding at 600° C. and a 0.1 μm thick membrane dielectric leaves a gap of 0.3 μm.

In some embodiments. different combinations of the Metal 2 thickness and membrane dielectric thickness are used to control gap between the membrane and the pedestal and different sandwich stacks to simultaneously achieve a desired capacitance value of the CMUT independent of the gap thickness.

In some embodiments, two plates of the CMUT embodied as the Metal 1 and the Metal 2 are electrically isolated from corresponding plates of other CMUT cells on a same die, this isolation enabling compensation of stray capacitances by suitable circuit techniques.

In some embodiments, a pedestal in one or more sizes and one or more shapes comprising interleaved and grid-like structures is constructed inside the cavity of the CMUT. In some embodiments, the pedestals enable lowering of the collapse voltage, enable lowering of operating voltages and improve control on a resonant frequency of vibration of the membrane.

The CMUT has an interleaved metal-insulator (silicon dioxide/silicon nitride or alternatively silicon dioxide/hafnium oxide sandwich) to reduce pull—in and collapse voltage. The CMUT includes reduced interlayer parasitic capacitance using a 2-metal process that surmounts a problem of stray capacitance along with increased inter-metal dielectric breakdown. The CMUT has low operating de voltage and a reduced spring softening effect. The CMUT enables feed of dc in series with ac voltage on both plates independently. This unlocks many circuit techniques to be applied on the CMUT that would otherwise not be possible. The CMUT enables reduction of a number of interconnects when used as a two-dimensional array. The CMUT has a high Electric field in the cavity (between the membrane and n+ bottom plate) increases the electro-mechanical efficiency of the CMUT.

In some embodiments, integrating getter materials in the SOI wafer provides a low-cost means of improving the vacuum level in the cavity, thereby increasing gas breakdown voltage and solving trapped gas-related problems.

The Titanium Polycide and conducting metal 1 layer below the pedestal results in a very simplified CMUT capacitance during Collapse. The doped Poly and the Titanium conducting layer ensure that the membrane characteristics and cavity gap is controlled by the design and properties of the Metal 2 in the top plate of the CMUT and the dielectric thickness within the cavity.

In some embodiments, the dielectric layer may be deposited on the pedestal in the bottom wafer.

In some embodiments, the dielectric layer may be on the device layer on the top wafer.

In some embodiments, the dielectric layer is entirely comprised of SiO2.

In some embodiments, the dielectric layer is comprised of a sandwich of silicon dioxide (SiO2) and Hafnium Oxide (HfO2).

In some embodiments, the dielectric layer is comprised of a sandwich of silicon dioxide (SiO2) and silicon nitride (Si3N4).

In some embodiments, a sandwich of one or more high relative permittivity materials may be used to form the dielectric layer.

In all embodiments, the dielectric layer results in an increased electrical field and increased CMUT capacitance in collapse and improved the electro-mechanical transduction efficiency.

The second type of CMUT also sits entirely above the silicon surface, has a conducting pedestal inside the cavity on the bottom wafer with a dielectric on the bottom of the device layer in the top wafer and may be a good fit in certain cases of post-integration to the Drive/Receive Electronics implemented in bulk CMOS in a Back-End Of the Line (BEOL) module. This can be accomplished either by using Through-Silicon-Via (TSV), which is not a high-yield technology yet, or by a Chip-on-Board (COB) or equivalent bonding technique.

The third type of CMUT uses silicon dioxide below each CMUT element for isolation between CMUTs. Both plates of the CMUT comprise aluminium (Metal 1 and Metal 2); a dielectric layer is deposited on Metal 1 and a conducting pedestal with or without an interleaved structure is constructed on it. The membrane is constructed of the silicon device layer in a top silicon wafer and bonded to the bottom wafer by silicon to silicon bonding.

The fourth type of the CMUT is a variant of the third type and additionally offers the facility to increase the fixed component of the CMUT capacitance, thereby enabling future scaling wherein smaller CMUT cell sizes can make interconnect parasitic become more significant, but a sandwich capacitor provides an answer without increasing silicon real estate.

The CMUT and some alternative implementations of the CMUT (and by extension a CMUT Array comprising either cells or cell elements) can be implemented completely on top of a CMOS (or other) device (BEOL with interconnections that do not require any low yield technology such as “through silicon vias” (TSVs).

The process steps in fabricating the CMUT are not high-cost or equipment-centric. The standard CMOS process steps, available in a moderately equipped foundry, will reduce the production cost. The electric field and the membrane capacitance are inversely proportional to the effective membrane gap. The high electric field and high membrane capacitance in the CMUT is achieved by introducing special structures in the membrane cavity. This reduces the effective gap between the membrane and the bottom plate, thereby increasing an electromechanical transduction efficiency, which is a product of electric field and membrane capacitance.

The electromechanical transduction efficiency η=E×C(i.e., a product of electric field and membrane capacitance). The CMUT improves both independently and a considerably enhanced output pressure on the acoustic port providing better control on range resolution and sensitivity.

The interleaved metal-insulator pedestal in the membrane cavity reduces the effective gap of the membrane, thereby reducing operating voltage which reduces the spring softening effect. Therefore, the shift in the center frequency is considerably reduced, which provides a better match in a 3-port CMUT cell model and device performance. This facilitates the prediction of more accurate values of the membrane 3-port elements reducing the prototyping time.

The presence of the pedestal serves two purposes. It focuses the electric field lines on to the (smaller) pedestal (compared to the entire surface of the bottom plate) and increases the electrostatic force and hence lowers the collapse voltage. Additionally, it reduces the effective radius of the membrane after collapse being restricted to the annular ring around the collapsed central part of the membrane. This increases the modal frequency.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications

### BRIEF DESCRIPTION OF THE DRAWINGS

The embodiments herein will be better understood from the following detailed description with reference to the drawings, in which:

FIGS. 1A-1B are flow diagrams that illustrate a method for designing a low voltage capacitive micromachined ultrasonic transducer (CMUT) according to some embodiments herein;

FIG. 2A is an exemplary diagram that illustrates performing dry oxidation of a silicon wafer to obtain a required silicon dioxide (SiO2) thickness of a base silicon wafer according to some embodiments herein;

FIG. 28 is an exemplary diagram that illustrates depositing a copper (Cu) or aluminium (Al) metal (M1) layer with a required thickness over the base oxide (SiO2) according to some embodiments herein;

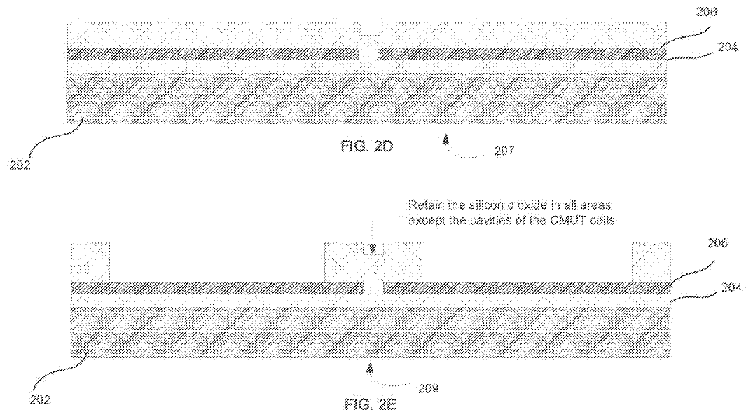

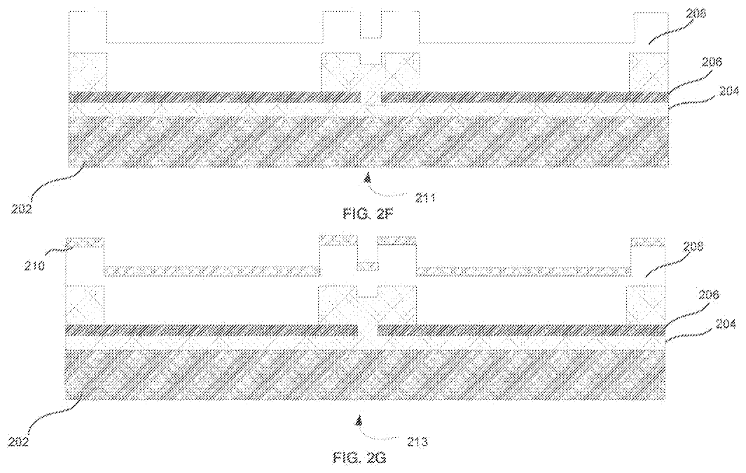

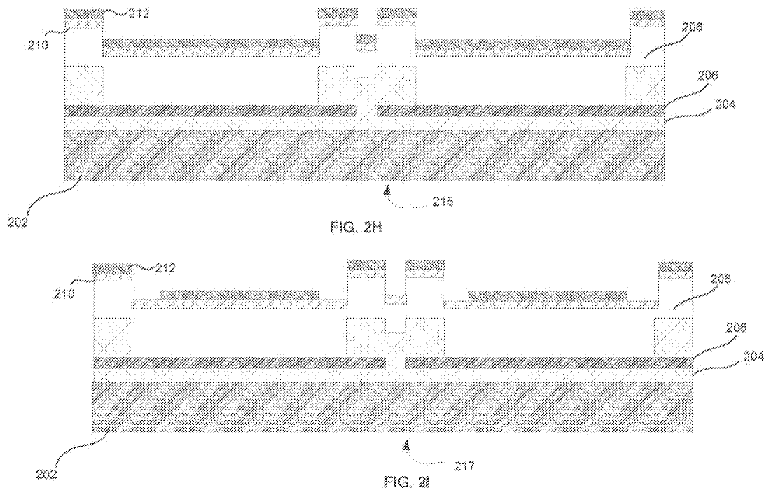

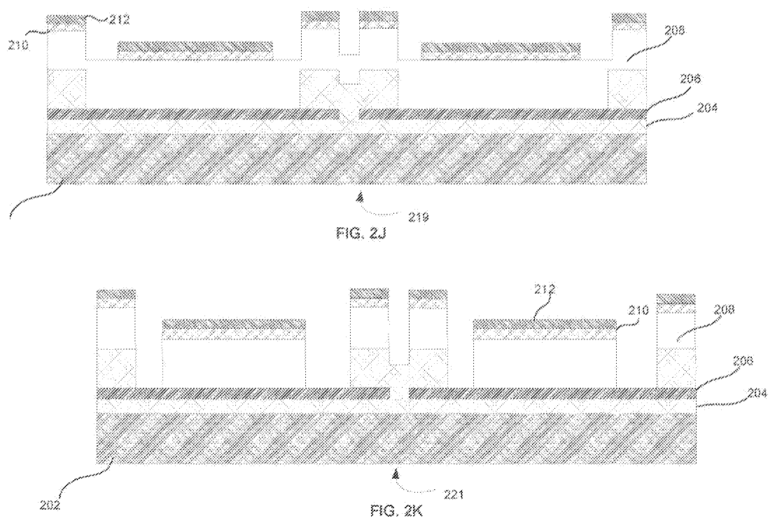

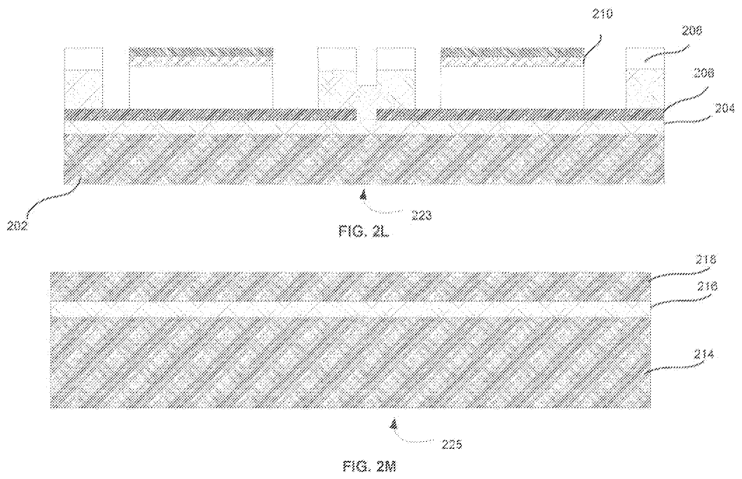

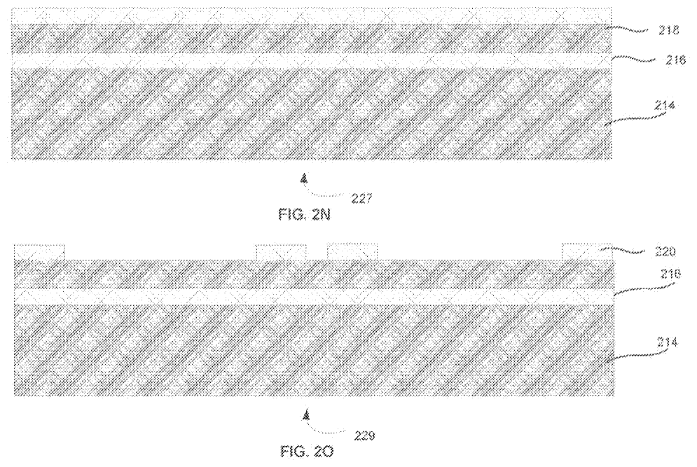

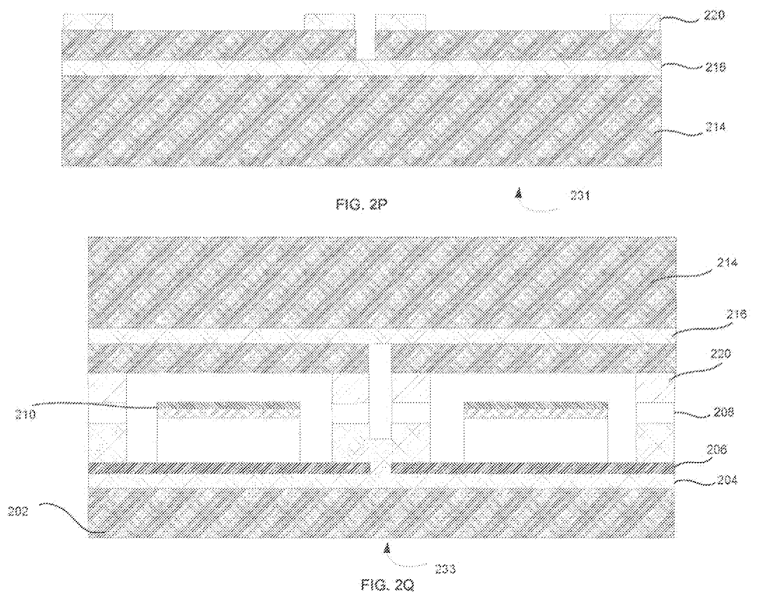

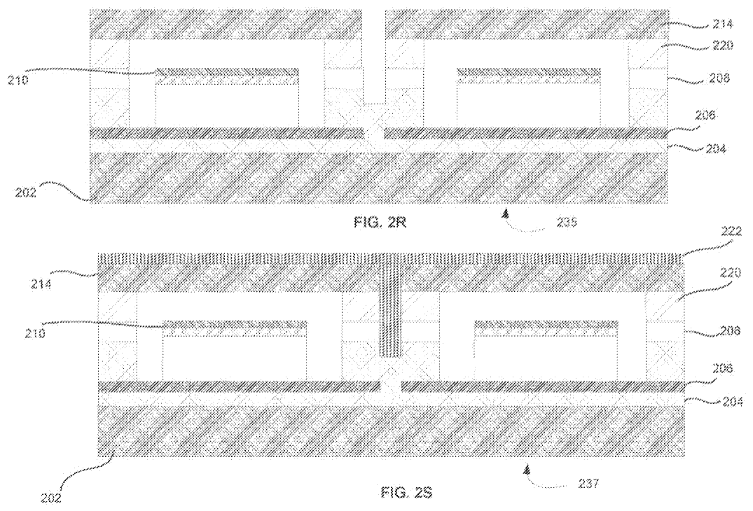

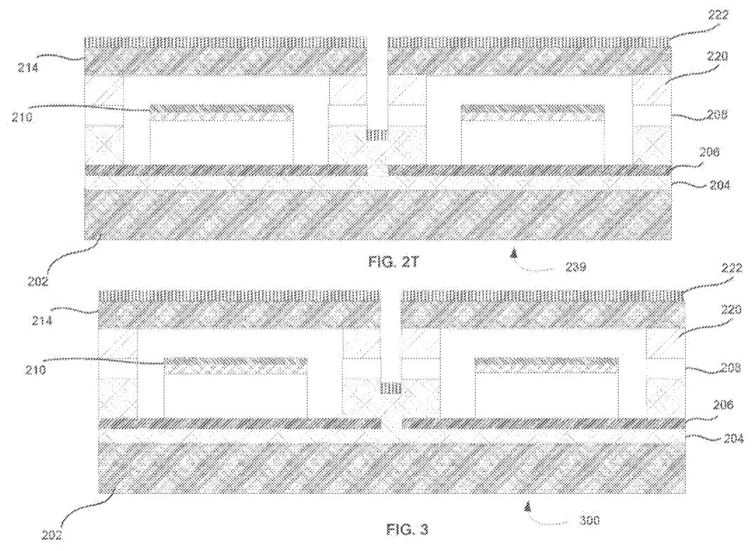

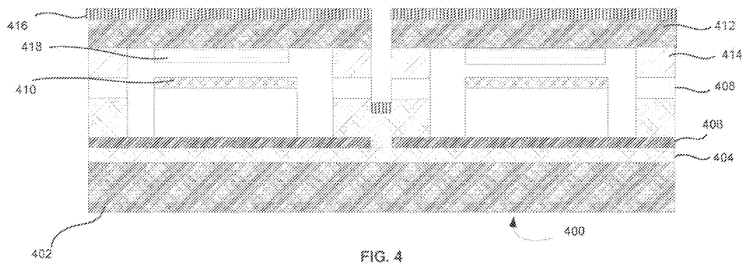

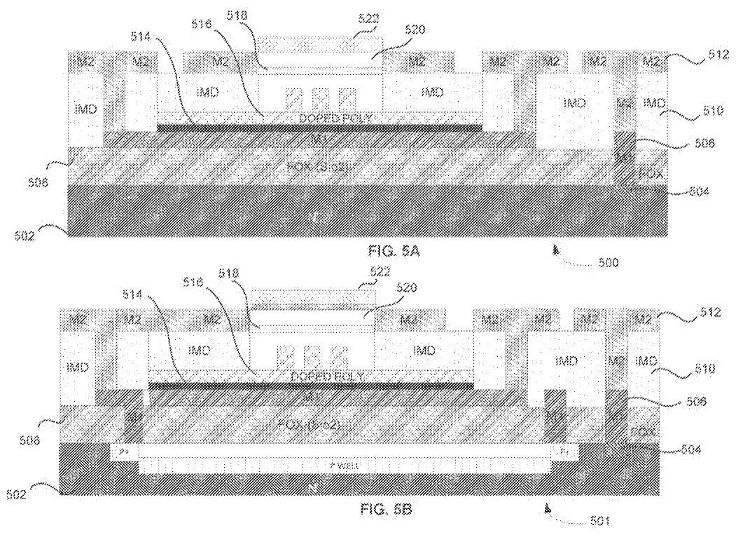

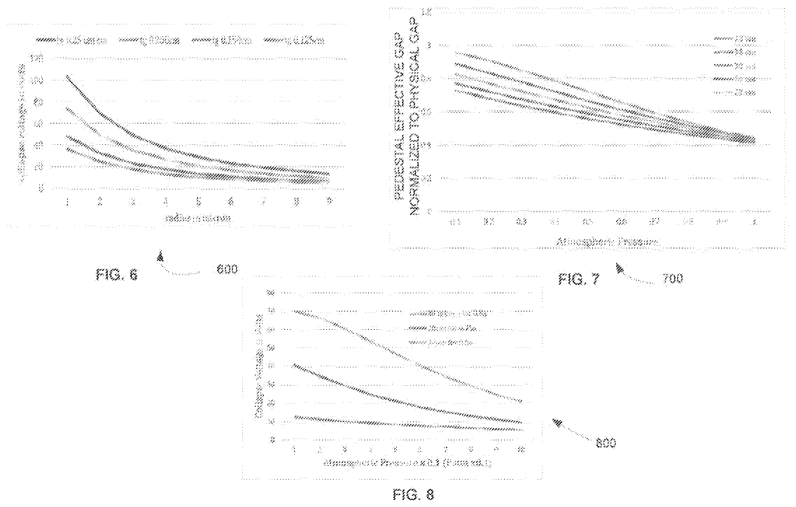

FIG. 2C is an exemplary diagram that illustrates patterning with a metal mask and etching the metal (M1) layer to create a CMUT bottom plate and a metal (M1) interconnect layer according to some embodiments herein:

FIG. 2D is an exemplary diagram that illustrates depositing a dielectric layer using Plasma-Enhanced Chemical Vapor Deposition (PECVD) over an entire silicon wafer according to some embodiments herein;

FIG. 2E is an exemplary diagram that illustrates patterning with a Field Oxide (FOX) Mask and etching the PECVD Oxide using buffer Hydrogen Fluoride (HF) solution to obtain CMUT cavities wafer according to some embodiments herein:

FIG. 2F is an exemplary diagram that illustrates depositing polysilicon over the entire silicon wafer according to some embodiments herein;

FIG. 2G is an exemplary diagram that illustrates subsequently depositing titanium (Ti) over doped polysilicon that is deposited on an entire silicon wafer according to some embodiments herein:

FIG. 2H is an exemplary diagram that illustrates subsequently depositing a dielectric layer some embodiments herein:

FIG. 2I is an exemplary diagram that illustrates patterning with a pedestal-poly mask over a dielectric layer that is deposited over the titanium and removing the patterned dielectric by a wet etch process according to some embodiments herein;

FIG. 2J is an exemplary diagram that illustrates removing exposed titanium by an alternative wet etch process according to some embodiments herein;

FIG. 2K is an exemplary diagram that illustrates excavating the polysilicon inside the cavity according to some embodiments herein:

FIG. 2L is an exemplary diagram that illustrates planarizing surface of the base silicon wafer by chemical mechanical polishing (CMP) according to some embodiments herein:

FIG. 2M is an exemplary diagram that illustrates starting with a separate top silicon wafer including a silicon “device” layer on top of buried oxide grown over a thick “handle” silicon layer according to some embodiments herein.

FIG. 2N is an exemplary diagram that illustrates depositing a Metal 2 over an entire wafer surface according to some embodiments herein;

FIG. 2O is an exemplary diagram that illustrates patterning with a Metal 2 Mask and etching the Metal 2 according to some embodiments herein;

FIG. 2P is an exemplary diagram that illustrates patterning with a CMUT Cell mask and etching the silicon “device” layer to define a CMUT top plate according to some embodiments herein;

FIG. 2Q is an exemplary diagram that illustrates aligning the separate top silicon wafer and the base silicon wafer according to some embodiments herein;

FIG. 2R is an exemplary diagram that illustrates chemical mechanical polishing (CMP) of the handle silicon layer by the RIE and a buried oxide layer by a wet etch process according to some embodiments herein;

FIG. 2S is an exemplary diagram that illustrates depositing a Polymer layer over an entire wafer according to some embodiments herein;

FIG. 2T is an exemplary diagram that illustrates patterning with a Polymer Mask and selectively etching the Polymer according to some embodiments herein;

FIG. 3 is a cross-sectional view of a Type 1 CMUT Cell according to some embodiments herein:

FIG. 4 is a cross-section view of Type 2 capacitive micromachined ultrasonic transducer (CMUT) according to some embodiments herein:

FIG. 5A is a cross-section view of Type 3 capacitive micromachined ultrasonic transducer (CMUT) according to some embodiments herein;

FIG. 5B is a cross-section view of Type 4 capacitive micromachined ultrasonic transducer (CMUT) according to some embodiments herein;

FIG. 6 is a graphical representation that depicts Collapse Voltage as a function of a membrane radius in μm for collapsed mode (CM) for membrane gap from 0.1 μm, 0.15 μm, 0.2 μm, and 0.25 μm according to some embodiments herein;

FIG. 7 is a graphical representation that depicts a normalised effective gap of a membrane for special structures in a cavity according to some embodiments herein; and

FIG. 8 is a graphical representation that depicts dependence of collapse voltage on size of a structure according to some embodiments herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

As mentioned, there remains a need for a capacitive micromachined ultrasonic transducer (CMUT) with a high electric field and high membrane capacitance achieved by introducing special structures in membrane cavity, thereby reducing an effective gap between a membrane and a bottom plate of the CMUT and increasing electromechanical transduction efficiency, which is a product of electric field and membrane capacitance.

The CMUT has a “pedestal” inside the cavity to control the onset of the deep collapse. Additionally, a conductor deposition step that further simplifies the modelling of capacitance in deep collapse leads to a simplified circuit design based on a 3-port small signal equivalent circuit model.

Further, a double metal process uses different layers of metal for the lower and upper plates of the CMUT, thereby enabling row-column addressing of the CMUT array to simplify the Drive Electronics.

There are four alternative implementations of the CMUT array. The first type of CMUT is significantly simpler, sits entirely above the silicon surface, has a conducting pedestal inside the cavity on the bottom wafer with a dielectric on top of the pedestal, and therefore a good fit for post-integration to the Drive 1 Receive Electronics implemented in bulk CMOS in a Back-End Of the Line (BEOL) module. This can be accomplished either by using Through-Silicon-Via (TSV), which is not a high-yield technology yet, or by a Chip-on-Board (COB) or equivalent bonding technique.

The second type of CMUT also sits entirely above the silicon surface, has a conducting pedestal inside the cavity on the bottom wafer with a dielectric on the bottom of the device layer in the top wafer and may be a good fit in certain cases of post-integration to the Drive/Receive Electronics implemented in bulk CMOS in a Back-End Of the Line (BEOL) module. This can be accomplished either by using Through-Silicon-Via (TSV), which is not a high-yield technology yet, or by a Chip-on-Board (COB) or equivalent bonding technique.

The fourth type of CMUT uses isolated wells below each CMUT element. These Wells can be maintained at different potentials with respect to the substrate. Using diffusion in these (isolated) Wells as one plate of a linear capacitor and the Metal 1 as the other plate with SiO₂ of suitable thickness as a dielectric, a high-valued constant capacitor can be created. When this diffusion layer is shorted to the top plate (M2) of the CMUT, a large, fixed value capacitance is effectively placed in parallel to the CMUT, thereby providing a mechanism to independently increase the CMUT capacitance and reduce the effect of interconnect parasitic on its performance.

It is possible to achieve this in a BEOL module using Metal 1 and the doped pedestal Polysilicon as the two plates of this linear capacitor. There may be other similar ways to accomplish this as well.

The use of titanium as gettering material is used to improve the cavity vacuum without using high-cost equipment. An ultrasound range transparent polymer is used which enhances the membrane peak deflection, which in turn increases the output ultrasound pressure for imaging and other applications.

A metal interleaved insulator structure is used to enhance the membrane peak deflection and by reducing the membrane to the pedestal gap it enhances the electric field and capacitance. This in turn enhances the electro-mechanical transduction efficiency.

All the new structures represented by first, second, third, and fourth types provide the capability of operating the CMUT cells at low de voltages in collapse mode. This provides higher beam deflection and in turn higher output ultrasound pressure. These are the salient features that improve the performance of the CMUT cell. The CMUT does not require ultra-high vacuum packaging requirement. The intended performance of vacuum packaging is alternatively accomplished using the gettering material.

A polymer on top of the membrane facilitates high membrane deflection and long life of the CMUT device. The selected polymer is such that it is transparent to the ultrasound frequency range of choice for the CMUT in question. In addition, the thickness of the polymer is chosen in a way such that it enhances the beam deflection. However, the use of polymer and its thickness dependence on the membrane deflection for higher output pressure has not been explored.

The problems of existing PZT-based imaging transducers have been addressed and solved with high range resolution and sensitivity CMUT-based array transducers that are ROHS compliant. Further, the new CMUT-based device configuration is inducted with a special structure to reduce the collapse voltage to operate the devices at low de voltages. In addition, the device can be fabricated using standard process steps of a conventional semiconductor foundry.

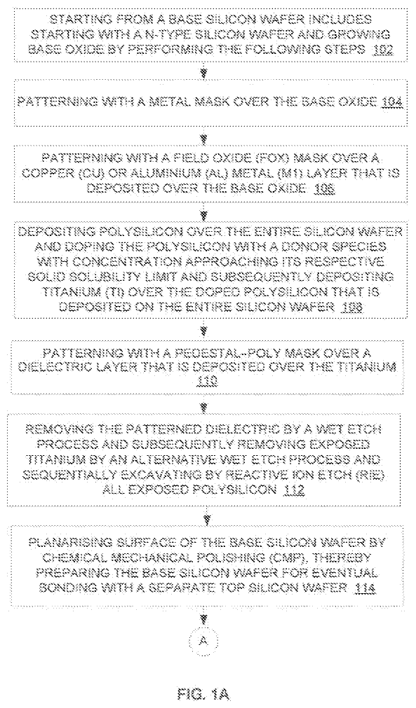

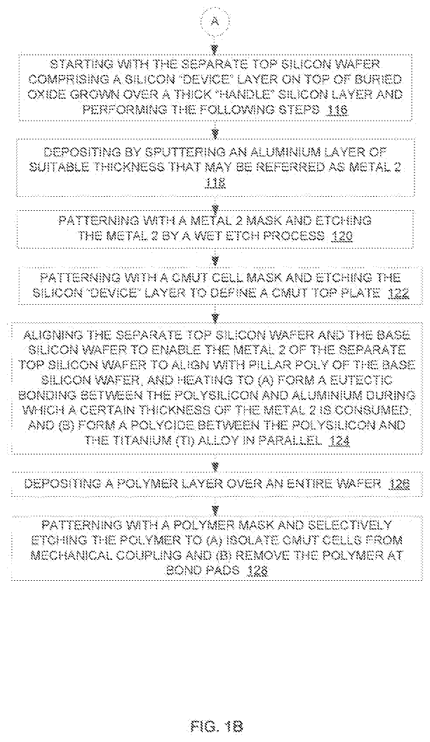

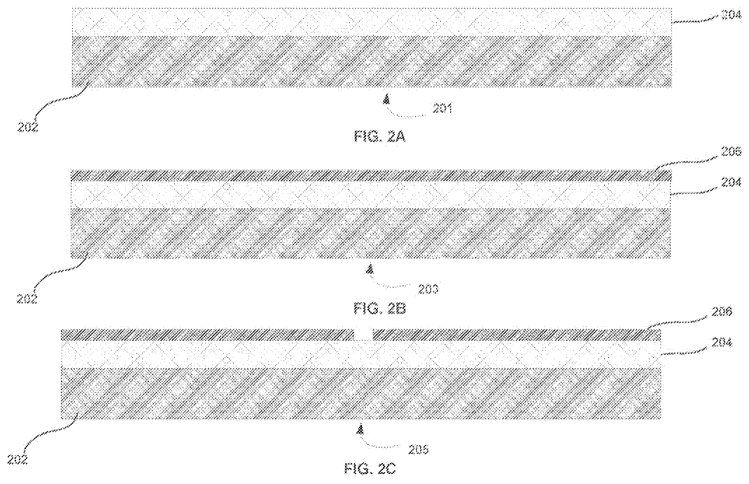

A 2-level metallization process is unique to the structure shown where the electronic circuitry and the membrane cavity can be independently processed and upgraded as the State of Art improves. Referring now to the drawings, and more particularly to FIGS. 1A through 8, where similar reference characters denote corresponding features consistently throughout the figures, there are shown preferred embodiments.

FIGS. 1A-1B are flow diagrams that illustrate a method for designing a low voltage capacitive micromachined ultrasonic transducer (CMUT) according to some embodiments herein. At step 102, started from a base silicon wafer includes starting with a N-type Silicon Wafer and growing base oxide by performing the following steps. At step 104, a metal mask is patterned over the base oxide. At step 106, a Field Oxide (FOX) Mask is patterned over a copper (Cu) or Aluminium (Al) metal (M1) layer that is deposited over the base oxide. At step 108, polysilicon is deposited over the entire silicon wafer and the polysilicon is doped with a donor species with a concentration approaching its respective solid solubility limit, titanium (Ti) is subsequently deposited over the (loped polysilicon that is deposited on the entire silicon wafer and a dielectric layer subsequently deposited. In some embodiments, the dielectric layer is Silicon Dioxide or in a stack with Hafnium Oxide or alternatively in a stack with Silicon Nitride or a high relative permittivity material.

At step 110, a pedestal-poly is patterned mask over a dielectric layer that is deposited over the titanium. At step 112, the patterned dielectric is removed by a wet etch process and exposed titanium is subsequently removed by an alternative wet etch process and sequentially excavating by reactive ion etch (RIE) all exposed polysilicon. At step 114, surface of the base silicon wafer is planarized surface of the base silicon wafer by chemical mechanical polishing (CMP), thereby preparing the base silicon wafer for eventual bonding with a separate top silicon wafer by chemical mechanical polishing (CMP), thereby preparing the base silicon wafer for eventual bonding with a separate top silicon wafer. At step 116, started with the separate top silicon wafer including a silicon “device” layer on top of buried oxide grown over a thick “handle” silicon layer and perform the following steps. At step 118, an aluminium layer is deposited by sputtering. The aluminium layer is Metal 2. At step 120, a Metal 2 Mask is patterned and the Metal 2 is etched by a wet etch process. At step 122, a CMUT Cell mask is patterned and the silicon “device” layer is etched by RIE to define a CMUT top plate. At step 124, the separate top silicon wafer and the base silicon wafer are aligned to enable the Metal 2 of the separate top silicon wafer to align with Pillar Poly of the base silicon wafer; and the separate top silicon wafer and the base silicon wafer are heated to enable the Metal 2 of the separate top silicon wafer to align with Pillar Poly of the base silicon wafer, and to (a) form a eutectic bonding between the polysilicon and aluminium during which a certain thickness of the Metal 2 is consumed, and (b) form a Polycide between the Polysilicon and the Titanium (Ti) alloy in parallel. The Titanium present inside the cavity (i) acts as a getter when the eutectic bonding is happening between the polysilicon and aluminium. (ii) forms chemical bonds with residual Nitrogen and Oxygen. and (c) removes the residual Nitrogen and Oxygen from the cavity, thereby improving vacuum in the cavity. At step 126, a Polymer layer is deposited over an entire wafer. At step 128, a Polymer Mask is patterned and the Polymer is selectively etched to (a) isolate CMUT cells from mechanical coupling and (b) remove the polymer at bond pads.

In some embodiment, the N-Type Silicon Wafer is replaced by P-Type Silicon Wafer. In some embodiments, concentration of the N-type Silicon Wafer is 5×10¹⁵/cm³, wherein the base oxide has 0.5 μm thickness.

In some embodiments, the method includes performing dry oxidation of a silicon wafer to obtain a required silicon dioxide (SiO2) thickness of the base silicon wafer, the dry oxidation is performed at 1050° C. for an appropriate time interval. The required oxide thickness is 1 μm. In some embodiments, the method includes depositing the copper (Cu) or aluminium (Al) metal (M1) layer with a required thickness over the base oxide (SiO2). In some embodiments, a thickness of the copper or Al metal 1 layer is based on a design specification of resistivity.

In some embodiments, the method includes etching the copper/Al metal using a wet etch process to create a CMUT bottom plate and a metal (M1) interconnect layer after the metal mask is patterned over the base oxide; and depositing conformally SiO2 using Plasma-Enhanced Chemical Vapor Deposition (PECVD) over an entire silicon wafer.

In some embodiments, the method includes etching the PECVD SiO2 after the Field Oxide (FOX) Mask is patterned using buffer Hydrogen Fluoride (HF) solution to obtain CMUT cavities.

In some embodiments, the method includes etching the dielectric layer using the wet etch process to expose the titanium from all areas where underlying poly is to be etched, wherein the dielectric layer is at least one of SiO2. SiO2/HfO2 sandwich or SiO2/Si3N4 sandwich.

In some embodiments, the method includes etching the Titanium by the wet-etch process where the polysilicon acts as an “etch-stop”, wherein the Titanium (Ti) is deposited over the polysilicon with a thickness of 100 nm by sputtering.

In some embodiments, the method includes excavating the polysilicon inside cavity around the pedestal and regions adjacent to pillars to prevent shorting of adjacent CMUTs.

In some embodiments, the Chemical Mechanical Polishing (CMP) is performed on the polysilicon with a thickness of 1.4 μm to remove the excess dielectric on the pillar; and the titanium (Ti) on pillar polysilicon and the excess height of the polysilicon to render the surface of a wafer planar.

In some embodiments, the method includes chemical mechanical polishing (CMP) of the handle silicon layer by RIFE and, sequentially, a buried oxide layer by the wet etch process.

In some embodiments, the separate top silicon wafer comprises a heavily doped top n+ silicon layer that is intended to be a membrane with a thickness of 2 μm, in some embodiments, the separate top silicon wafer comprises the thick handle silicon layer that is removed by RIE and the buried oxide layer placed below with the thickness of 0.5 μm which is removed by the wet-etch process with the silicon device layer acting as etch-stop for its removal.

In some embodiments, the Metal 2 of thickness 0.8 μm is reduced to 0.4 μm during eutectic bonding at 600° C. and a 0.1 μm thick membrane dielectric leaves a gap of 0.3 μm. In some embodiments, different combinations of the Metal 2 thickness and membrane dielectric thickness are used to control gap between the membrane and the pedestal and different sandwich stacks to simultaneously achieve a desired capacitance value of the CMUT independent of the gap thickness.

In some embodiments, two plates of the CMUT embodied as the Metal 1 and the Metal 2 are isolated from corresponding plates of other CMUT cells on a same die, this isolation enabling compensation of stray capacitances by suitable circuit techniques.

In some embodiments, a pedestal in one or more sizes and one or more shapes comprising interleaved and grid-like structures is constructed inside the cavity of the CMUT. In some embodiments, the pedestals enable lowering of the collapse voltage, enable lowering of operating voltages and improve control on a resonant frequency of vibration of the membrane.

FIG. 2A is an exemplary diagram 201 that illustrates performing dry oxidation of a silicon wafer 202 to obtain a required silicon dioxide (SiO2) thickness of a base silicon wafer according to some embodiments herein. The exemplary diagram 201 includes the silicon wafer and silicon dioxide (SiO2) 204. In some embodiments, the dry oxidation is performed at 1050° C. for an appropriate time. In sortie embodiments, the required oxide thickness is 1 μm. The functions of these components have been explained above.

FIG. 2B is an exemplary diagram 203 that illustrates depositing a copper (Cu) or aluminium (Al) metal (M1) layer 206 with a required thickness over the base oxide (SiO2) 204 according to some embodiments herein. In some embodiments, the copper or Al metal 1 layer 206 is deposited with a thickness of 0.2 μm. The functions of these components have been explained above.

FIG. 2C is an exemplary diagram 205 that illustrates patterning with a metal mask over the base oxide 204 according to some embodiments herein. The functions of these components have been explained above.

FIG. 2D is an exemplary diagram 207 that illustrates depositing a dielectric layer according to some embodiments herein. In some embodiments, the dielectric layer is deposited with a thickness of 1.5 μm using the PECVD. The functions of these components have been explained above.

FIG. 2E is an exemplary diagram 209 that illustrates patterning with a Field Oxide (FOX) Mask and etching the PECVD Oxide using buffer Hydrogen Fluoride (HF) solution to obtain CMUT cavities wafer according to some embodiments herein. The functions of these components have been explained above.

FIG. 2F is an exemplary diagram 211 that illustrates depositing polysilicon 208 over the entire silicon wafer according to some embodiments herein. The polysilicon 208 is deposited over the entire silicon wafer and the polysilicon 208 is doped with a donor species with a concentration approaching its respective solid solubility limit. In some embodiments, the polysilicon 208 is deposited on the etched PEVCD Oxide with the thickness of 2 μm using Low-Pressure Chemical Vapor Deposition (LPCVD).

FIG. 2O is an exemplary diagram 213 that illustrates subsequently depositing titanium (Ti) over the doped polysilicon that is deposited on the entire silicon wafer according to some embodiments herein. The functions of these components have been explained above.

FIG. 2IH is an exemplary diagram 215 that illustrates subsequently depositing a dielectric layer 212 some embodiments herein. The dielectric layer 212 is Silicon Dioxide or in a stack with Hafnium Oxide or alternatively in a stack with Silicon Nitride or a high relative permittivity material.

FIG. 2I is an exemplary diagram 217 that illustrates patterning with a pedestal-poly mask over the dielectric layer 212 that is deposited over the titanium 210 and removing the patterned dielectric by a wet etch process according to some embodiments herein. The functions of these components have been explained above.

FIG. 2A is an exemplary diagram 219 that illustrates removing exposed titanium by an alternative wet etch process according to some embodiments herein. The functions of these components have been explained above.

FIG. 2K is an exemplary diagram 221 that illustrates excavating the polysilicon 208 inside the cavity according to some embodiments herein. The polysilicon 208 inside the cavity is excavated and the pedestal is formed by an anisotropic Reactive Ion Etch (RIE) with a photoresist protecting the Ti 210. The pedestal is a structure that controls onset of deep collapse.

FIG. 2L is an exemplary diagram 223 that illustrates planarizing surface of the base silicon wafer by chemical mechanical polishing (CMP) according to some embodiments herein. In some embodiments, the Chemical Mechanical Polishing (CMP) is performed on the polysilicon 208 with a thickness of 1.4 μm to remove the Titanium (Ti) 210 on pillar polysilicon and the excess height of the polysilicon 208 to render the surface of a wafer planar.

FIG. 2M is an exemplary diagram 225 that illustrates starting with a separate top silicon wafer including a silicon “device” layer on top of buried oxide 216 grown over a thick “handle” silicon layer according to some embodiments herein. In some embodiments, the separate top silicon wafer includes a heavily doped top n+ silicon layer 218 that is intended to be a membrane with a thickness of 2 μm. In some embodiments, the separate top silicon wafer includes the thick handle silicon layer that is removed by the RIE and the buried oxide layer 216 placed below with the thickness of 0.5 μm which is removed by the wet-etch process with the silicon device layer acting as etch-stop for its removal.

FIG. 2N is an exemplary diagram 227 that illustrates depositing a Metal 2 220 over an entire wafer surface according to some embodiments herein. In some embodiments, the Metal 2 220 is deposited over the entire top wafer with a thickness of 0.8 μm.

FIG. 2O is an exemplary diagram 229 that illustrates patterning with a Metal 2 Mask and etching the Metal 2 220 according to some embodiments herein. The functions of these components have been explained above.

FIG. 2P is an exemplary diagram 231 that illustrates patterning with a CMUT Cell mask and etching the silicon “device” layer to define a CMUT top plate according to some embodiments herein. The functions of these components have been explained above.

FIG. 2Q is an exemplary diagram 233 that illustrates aligning the separate top silicon wafer and the base silicon wafer according to some embodiments herein. The separate top silicon wafer and the base silicon wafer ae aligned to enable the Metal 2 220 of the separate top silicon wafer to align with Pillar Poly of the base silicon wafer, and the separate top silicon wafer and the base silicon wafer are heated to (a) form a eutectic bonding between the polysilicon and aluminium during which a certain thickness of the Metal 2 220 is consumed, and (b) form a Polycide between the Polysilicon and the Titanium (Ti) alloy in parallel. The Titanium present inside the cavity (i) acts as a getter when the eutectic bonding is happening between the polysilicon and aluminium, (ii) forms chemical bonds with residual Nitrogen and Oxygen. and (c 1 removes the residual Nitrogen and Oxygen from the cavity, thereby improving vacuum in the cavity.

In some embodiments, the Metal 2 220 of thickness 0.8 μm is reduced to 0.4μ during eutectic bonding at 600° C. and a 0.1 μm membrane dielectric leaves a gap of 0.3 μm. In some embodiments, different combination of the Metal 2 220 thickness and membrane dielectric thickness are used to control gap between the membrane and the pedestal and different sandwich stacks to simultaneously achieve a desired capacitance value of the CMUT independent of the gap thickness.

FIG. 2R is an exemplary diagram 235 that illustrates chemical mechanical polishing (CMP) of the handle silicon layer by the RIE and a buried oxide layer by a wet etch process according to some embodiments herein. The functions of these components have been explained above.

FIG. 2S is an exemplary diagram 237 that illustrates depositing a Polymer layer 222 over an entire wafer according to some embodiments herein. The functions of these components have been explained above.

FIG. 2T is an exemplary diagram 239 that illustrates patterning with a Polymer Mask and selectively etching the Polymer 222 according to some embodiments herein. The Polymer Mask is patterned, and the Polymer 222 is selectively etched to (a) isolate CMUT cells from mechanical coupling and (b) remove the polymer at bond pads.

FIG. 3 is a cross-sectional view of a Type 1 CMUT Cell 300 according to some embodiments herein. The cross-sectional view of the Type 1 CMUT Cell 300 includes the silicon wafer 202, the silicon dioxide (SiO2) 204, the metal 1 (M1) 206, the polysilicon 208, the Titanium 210, the heavily doped top n+ silicon layer 218, the Metal 2 220, and the polymer 222.

In some embodiments, the CMUT 300 doesn't include bulk silicon and can be constructed entirely using two metals such as the metal 1 (M1) 206 and the metal 2 (M2) 220. In some embodiments, membrane dielectric can be for example a 100 nm layer of silicon dioxide grown by dry oxidation. In some embodiments, a resonant frequency of the CMUT 300 is determined using geometry and material properties of the CMUT 300.

In some embodiments, a multi-frequency CMUT is obtained by exploiting two properties of CMUTs by (i) making a cluster of a finite number of interconnected CMUTs where each has a different resonant frequency and (ii) exploiting a property, where possible, that a given CMUT apart from its fundamental resonance also exhibits overtone type higher order resonance modes, in some embodiments, the cluster of the finite number of CMUTs is referred as a CMUT Element to distinguish it from the CMUT 300. The property may be exploited to minimize the number of CMUTs in the cluster while maximizing a number of discrete frequencies within a certain pre-determined band.

In some embodiments the CMUT 300 has 30-120 μm diameter and a centre-to-centre spacing to maintain conductors within each unit cell isolated from adjacent cells, thereby preventing any dielectric breakdown under normal usage. When configured as an element that includes one or more CMUTs depending on a desired frequency range, resolution, and sensitivity. In some embodiments, a 15 MHz range for example can be accomplished with 4 such cells. In some embodiments, inter-elemental separation is suitably determined from electrical and dielectric field breakdown considerations. In some embodiments, an inter-elemental separation of the CMUT 300 is 25 μm. Each element of the CMUT 300 is configured as an array that can be independently driven while implementing a phase array concept or compressive sampling. In some embodiments, a two-dimensional array is designed using the CMUT 300 shown in FIG. 3 can perform a function of any suitable orthogonal code implementation. The CMUT 300 can be designed fir higher order multi-frequency oscillations to optimize a number of cells in the element, thereby enabling a maximum number of discrete frequencies which may lower a number of distinct CMUT cells/elements to cover an entire ultrasonic frequency band. Further, multi-frequency oscillations are exploited for automotive applications by using the spread spectrum communication which increases a range resolution at lower power transmission. In some embodiments, any further multiplexed frequency and higher modal frequency with appropriate filtering operation can be used to detect low-flying objects such as Drones. In some embodiments, an application of spread spectrum in conjunction with multi-frequency operation and reduced sampling technique (compressive sampling) is used for generating higher modal frequencies and can be implemented using the CMUT 300.

In some embodiments, performance evaluation parameters in comparison with standard CMUT cells highlighted in the block diagram FIG. 3 can be summarized to provide improved performance on i) feasibility of using a smaller radius of the CMUT 300 providing the capability of operating at a higher frequency (18.836 MHz) with the capability of using orthogonal codes for Tx/Rx, ii) higher vacuum in comparison with standard packaging schemes by using a gettering layer for residual gas absorption, iii) higher membrane deflection by the use of appropriately chosen polymer, which is transparent to an ultrasound frequency band, iv) considerably reduced collapse voltage using special structures in the cavity, which are conductive and enhances the electrical field, v) enhanced electro-mechanical transduction leading to higher output ultrasonic pressure increasing the range resolution, and vi) use of three port small signal equivalent circuit model to predict consistency in the prototype and simulated devices because of negligible spring softening effect.

In some embodiments, a starting N-type wafer is at least one of undoped silicon or even oxide in a BEOL configuration. In some embodiments, the starting material is a plane substrate such as glass. In some embodiments, the photoresist is positive. In some embodiments, the positive photoresist is a photoactive polymer that when exposed to UV gets its bonds broken so that a subsequent “development” of photoresist results in the field regions exposed to UV being dissolved by a chemical process that leaves unexposed regions undisturbed.

FIG. 4 is a cross-section view 400 of Type 2 capacitive micromachined ultrasonic transducer (CMUT) according to some embodiments herein. The cross-sectional view of the Type 2 CMUT Cell 4100 includes a silicon wafer 402, silicon dioxide (SiO2) 404, a metal 1 (M1) 406, polysilicon 408, Titanium 410, a heavily doped top n+ silicon layer 412, a Metal 2 414, polymer 416 and membrane dielectric 418. The cross-section view 400 depicts the sandwiched membrane dielectric 418 in the top wafer to create a high fixed value capacitance in Collapse of the CMUT. In some embodiments, the Type 2 can be constructed using top two levels of Metal. In some embodiments, the membrane cavity, as in the Type 1 CMUT has the pedestal structure to precisely control the effective gap for reducing the collapse voltage. In some embodiments, the Type 2 CMUT can be constructed with SiO2 on a membrane replaced by a SiO2-HfO2-SiO2 sandwich. In some embodiments, the Type 2 CMUT can be constructed with SiO2 on a membrane replaced by a SiO2-Si3N4 sandwich, in some embodiments, the Type 2 CMUT can be constructed with SiO2 on a membrane replaced by a SiO2-Si3N4-SiO2 sandwich.

FIG. 5A is a cross-section view 500 of Type 3 capacitive micromachined ultrasonic transducer (CMUT) according to some embodiments herein. The CMUT includes a n-type wafer substrate 502, a n-type diffusion in a substrate 504, metal 1 (M1) 506, Field Oxide (FOX: SiO2) 508, an inter-metal dielectric (IMD) 510, metal 2 (M2) 512, a base oxide layer 514, n+ doped poly 516, a gettering layer 518, Si membrane n⁺ 520 and polymer 522. In some embodiments, the n-type wafer 502 is <100> Crystal Orientation Silicon Wafer. In some embodiments, concentration of the silicon wafer is 10¹⁵/cm³. The CMUT is fabricated using a base wafer process and a top SOI Wafer process. The base wafer process of the CMUT includes developing base oxide (SiO₂) and Nitride (Si₃N₄) sandwich over the n-type wafer 502 and coating photoresist over the base oxide (SiO₂) and Nitride (Si₃N₄) sandwich. The base wafer process includes making an N⁺ Mask (Light Field) by developing the photoresist, etching the base oxide (SiO₂) and the Silicon Nitride (Si₃N₄) from field regions, and thermally growing or depositing Field Oxide (FOX: SiO₂).

The base wafer process further includes stripping the photoresist and etching the base oxide (SiO₂) and the Silicon Nitride (Si₃N₄). The base wafer process further includes implanting high concentration and low energy n⁺ type dopants such as the n⁺ type substrate diffusion 504, depositing the M1 506, and driving the M1 506 in the n⁺ type substrate 504, in some embodiments, the M1 506 is used to stop out-gassing during drive-in.

The base wafer process further includes growing thin oxide thermally over the M1 506, depositing polysilicon on the thin oxide, and doping the poly with n⁺ to solid solubility limit. The base wafer process further includes depositing Si₃N₄ over the doped poly with n⁺516 and coating the photoresist over the Si₃N₄.

In some embodiments, Poly height is calculated by

Poly height=flat portion of a top plate of the CMUT+pedestal height

In some embodiments, Nitride height is calculated by

Nitride height=CMUT cavity height−Poly height.

The base wafer process further includes making a Metal 1 Mask (LF) by developing the photoresist over the Metal 1 Mask (LF), etching Nitride, and etching Poly from non-CMUT regions. The base wafer process further includes etching the M1 506 and stripping the photoresist and coating the photoresist.

The base wafer process further includes making a CMUT Membrane Mask by developing the photoresist over the CMUT Membrane Mask and etching the Nitride and the Poly. The base wafer process further includes growing the Inter-Metal Dielectric (IMD) 510, stripping the photoresist, and coating fresh photoresist.

The base wafer process further includes making a CMUT Pedestal Mask (Dark Field (DF) by developing the photoresist over the CMUT Pedestal Mask (DF) and etching the Nitride and the Poly. The base wafer process further includes depositing the poly(base conducting layer of the top plate), doping the n⁺ 504 on the Poly to solid solubility limit, stripping the photoresist, and subsequently coating the photoresist. The n⁺ dopant is implanted with a high concentration and low energy. In some embodiments. Deep Reactive Ion Etching (DRIE) is employed to etch out an annular cavity around the CMUT Pedestal Mask (DF). The CMUT Pedestal Mask (Dark Field (DF)) is made by developing the photoresist over the CMUT Pedestal Mask (DF) and etching the Nitride and the Poly. The CMUT Pedestal Mask (Dark Field (DF) is made by depositing the poly(base conducting layer of the top plate), doping the n⁺ 504 on the Poly to solid solubility limit, stripping the photoresist, and coating the photoresist.

The base wafer process further includes making a CMUT Poly Mask (LF) by developing the photoresist over the CMUT Poly Mask (LF), etching the Poly over the IMD 510, stripping the photoresist, and etching the Nitride.

The top SOI Wafer process includes starting with a top SOI Silicon wafer with an N-type <100> device layer with a buried SiO2 layer with a top silicon handle layer In some embodiments, concentration of the N⁻ device layer is 10¹⁸/cm³. The top SOI Wafer process includes etching device silicon to desired (membrane) thickness, depositing titanium (getter) on the silicon device layer, bonding it to the base wafer, removing the handle, and coating the photoresist.

The top SOI Wafer process includes making the CMUT Membrane Mask (LF) with slight oversizing by developing the photoresist, etching SiO₂, and etching Si from non-CMUT areas. The top SOI Wafer process further includes stripping and coating fresh photoresist. The tip SON Wafer process further includes making via Mask (DF) by developing the photoresist, etching the IMD 510 via contacts and SiO₂ over the membrane, stripping the photoresist, depositing the Metal 2 512, and coating fresh photoresist over the Metal 2 512.

The top SOI Wafer process further includes making the Metal 2 512 (LF) by developing the photoresist, etching the Metal 2 512, stripping the photoresist, depositing the Polymer 522, and coating the photoresist. The top SOI Wafer process further includes making the Polymer mask (LF) by developing the photoresist, etching the Polymer 522, and stripping the photoresist. In some embodiments, the Polymer mask (LF) is oversize than the CMUT Membrane Mask.

FIG. 5B is a cross-section view 501 of Type 4 capacitive micromachined ultrasonic transducer (CMUT according to some embodiments herein. The CMUT includes a n-type wafer substrate 502, a n⁺ type diffusion in a substrate 504, metal 1 (M1) 506, Field Oxide (FOX: SiO2) 508, an inter-metal dielectric (IMD) 510, metal 2 (M2) 512, a base oxide layer 514, n⁺ doped poly 516, a gettering layer 518, Si membrane n⁺ 520 and polymer 522. In this implementation, the type 5 of CMUT can be constructed with a Linear Capacitor sandwiched below the CMUT as shown in FIG. 58 either using Diffusion or Poly or Metal for each plate of this linear capacitor. In some embodiments, a combination of n⁺ well in p-well realized on an i-type substrate. In some embodiments, the Type 4 of the CMUT includes the sandwiched nitride and oxide layer to create a high fixed value capacitance that sits in parallel to the CMUT. In an integrated implementation this Type 4 can be constructed using the top two levels of Metal combined with a linear capacitor module if available. The membrane cavity, as in the Type 3 CMUT, has a special structure to decrease the effective gap for reducing the collapse voltage.

In some embodiments, a resonant frequency is primarily determined by the Young's Modulus, the Poisson's ratio, elastic constant, which are the primary physical parameters of the membrane in conjunction with membrane thickness and its radius.

In some embodiments of Type 1 and Type 2 CMUT, the resonant frequency of the CMUT typically reduces by a factor of 9% with increasing membrane radius for a fixed membrane thickness of 1.5 μm. The percentage decrease in frequency is about 11% as the membrane thickness reduces to about 1 μm. The fundamental mode of vibration will depend on the external force exerted on the membrane and the radius of the membrane in conjunction with the membrane thickness.

Table 1 shows the frequency dependence as a function of the membrane radius for a few values of membrane thicknesses from 1 μm and a fixed gap “tg” of 0.25 μ in a Type 1 Si/SiO2 membrane structure,

| | Frequency in MHz | Frequency in MHz | Frequency in MHz |
|---|---|---|---|
| Radius | for 1 μm thick | for 1.25 mm thick | for 1.5 μm thick |
| μm | membrane | membrane | membrane |
| 18 | 11.2 | 14.1 | 16.9 |
| 20 | 9.1 | 11.4 | 13.7 |
| 22 | 7.5 | 9.4 | 11.3 |
| 24 | 6.35 | 7.9 | 9.52 |
| 26 | 5.4 | 6.7 | 8.1 |
| 28 | 4.6 | 5.8 | 7 |
| 30 | 4.06 | 5.07 | 6.1 |
| 32 | 3.56 | 4.46 | 5.35 |
| 34 | 3.16 | 3.95 | 4.74 |
| 36 | 2.82 | 3.52 | 4.23 |
| 38 | 2.5 | 3.16 | 3.79 |
| 40 | 2.28 | 2.85 | 3.4 |
| 45 | 1.8 | 2.25 | 2.7 |
| 50 | 1.4 | 1.82 | 2.18 |
| 55 | 1.2 | 1.51 | 1.81 |

Since, the collapse voltage also depends on the membrane thickness, and its gap, therefore a judicious tradeoff is required to be made between these parameters to achieve a low collapse voltage. The radius of the CMUT is used to determine the operating frequency as a function of membrane gap. There are options of reducing the collapse voltage: a) reducing the membrane gap for a given thickness and membrane radius, b) by reducing the membrane effective gap (vacuum gap+ dielectric thickness/dielectric constant of insulating layer) c) using the dielectric special structure (pedestal) in the cavity, and d) making the judicious choice of the special structure in the cavity of conducting layer with very low resistivity.

TABLE 2
Collapse mode of operation of Si—SiO2 structure
using dielectric pedestal in the membrane cavity.

| | Membrane | Membrane | Membrane | Membrane |
|---|---|---|---|---|
| Radius | gap “tg” | gap “tg” | gap “tg” | gap “tg” |
| μ | 0.25μ | 0.2μ | 0.15μ | 0.125μ |
| 18 | 103 | 73.76 | 47.99 | 36.46 |
| 22 | 69 | 49.38 | 32.12 | 24.42 |
| 26 | 49.4 | 35.35 | 23 | 17.47 |
| 30 | 37.1 | 26.55 | 17.27 | 13.127 |
| 34 | 28.89 | 20.67 | 13.45 | 10.22 |
| 38 | 23.13 | 16.55 | 10.76 | 8.18 |
| 42 | 18.93 | 13.548 | 8.81 | 6.69 |
| 46 | 15.78 | 11.29 | 7.34 | 5.583 |
| 50 | 13.36 | 9.56 | 6.22 | 4.72 |

A lowered collapse voltage of the membrane is achieved by increasing the electric field in the cavity for the same physical parameters of the CMUT cell. However, the radius of the membrane, the membrane thickness and the membrane gap affect the collapse voltage. Larger the membrane radius, and/or smaller the membrane thickness and/or smaller is the membrane gap, it be will easier to collapse the membrane at lower DC voltages.

For smaller radius where the arch of the membrane deflection is small, the CMUT cell operates at higher frequencies but the membrane deflection is not adequate to collapse the membrane. Therefore, it is desirable to induct special dielectric/conducting structure in the membrane cavity to enhance the electric field by reducing the effective membrane gap of the cavity.

The effect of using a dielectric stack in the membrane cavity is shown in FIG. 3 for standard Si—SiO2 structure, where the SiO2 layer can be changed by a dielectric stack. These results are for example shown for a constant membrane thickness of 1.25 μm for all values of radii and membrane gap as shown in Table 2. In the solution disclosed here, as an example a pedestal with a diameter of 0.75 times of the membrane diameter is inducted in the cavity for all physical membrane gaps. The effect of introducing the pedestal in the membrane cavity is evident for smaller radius (18 μm) with relatively large membrane gap (0.25 μm) in column 1 and 2 of Table 2, because it enhances the electric field thereby decreases the collapse voltage.

The results show the collapse voltage getting reduced by 50% for Si—SiO2 for smaller radius and about 40% for larger radius.

FIG. 6 is a graphical representation 600 that depicts shows Collapse Voltage as a function of a membrane radius in μm for collapsed mode (CM) for membrane gaps 0.1 μm, 0.15 μm, 0.2 μm, and 0.25 μm for a collapse mode (CM) according to some embodiments herein. In FIG. 6 of the graphical representation 600, the membrane radius in μm is plotted on an X-axis and the collapse voltage in volts is plotted on a Y-axis.

The graphical representation 600 depicts dependence of the collapse voltage on the membrane gap as a function of the membrane radius as the membrane radius is varied from 18 μm to 50 μm for membrane gaps of 0.125 μm, 0.15 μm 0.20 μm, and 0.25 μm. In some embodiments, the CMUT 300 operating with the radii in the range of 34 μm to 50 μm can have its operating voltages reduced to below 40 volts. In some embodiments, the CMUT 300 can reduce the Collapse Voltage and thereby lower the operating voltage for a lower membrane radius.

The CMUT cell can be operated at low DC voltage by using a thin membrane, and/or smaller membrane gap, together with special structures such as the pedestal in the membrane cavity. A method to control the membrane gap is to reduce the effective gap which is defined to be the vacuum gap added to dielectric thickness divided by its dielectric constant. This is facilitated by the use of high dielectric constant materials. The use of a high dielectric layer is desirable in all the CMUT structures because we need to protect the membrane from damage during the collapse mode of operation. It is always advantageous to use a high “k” dielectric stack such as SiO2/HfO2, because it reduces the collapse voltage by a factor of square root of the dielectric constant. A proper design of thickness of each layer on the basis of breakdown leakage current and finally operating the CMUT cell with a considerably higher effective dielectric constant. Additionally, the use of materials with high effective dielectric constant increases the membrane capacitance.

TABLE 3
Variation of normalized effective gap (gap normalized with
dielectric constant) of membrane for different values of
atmospheric pressure. The membrane thickness, physical cavity
gap, oxide thicknesses for the Si—SiO2 structures are
chosen to be 1.25 μm, 0.25 μm, and 0.125 μm, respectively.

| | Normal- | Normal- | Normal- | Normal- | Normal- |
|---|---|---|---|---|---|
| Normal- | ized | ized | ized | ized | ized |
| ized | gap for | gap for | gap for | gap for | gap for |
| Atmospheric | radius | radius | radius | radius | radius |
| pressure | 22μ | 26μ | 30μ | 34μ | 38μ |
| 0.1 | 0.728 | 0.772 | 0.825 | 0.888 | 0.957 |
| 0.2 | 0.68 | 0.722 | 0.772 | 0.834 | 0.909 |
| 0.3 | 0.636 | 0.675 | 0.721 | 0.778 | 0.85 |
| 0.4 | 0.595 | 0.63 | 0.673 | 0.721 | 0.786 |
| 0.5 | 0.557 | 0.589 | 0.624 | 0.665 | 0.72 |
| 0.6 | 0.522 | 0.55 | 0.579 | 0.612 | 0.655 |
| 0.7 | 0.491 | 0.515 | 0.538 | 0.563 | 0.594 |
| 0.8 | 0.462 | 0.482 | 0.499 | 0.517 | 0.537 |
| 0.9 | 0.436 | 0.452 | 0.464 | 0.475 | 0.485 |
| 1 | 0.411 | 0.424 | 0.431 | 0.436 | 0.439 |

The effective gap is sum of the vacuum gap+ dielectric thickness/its dielectric constant. Whereas, the physical gap is the sum of the vacuum and dielectric thickness of the membrane cavity. In present case the physical gap is 0.25 μm, which comprised of SiO2 thickness to 0.1 μm and 0.15 μm of vacuum, then the effective gap is (0.15+0.1/3.9=0.1756 μm). The physical gap of the membrane cavity is 0.25 μm and effective gap with the pedestal is 0.1756 μm. The dependence of the effective gap on the pressure is governed by the change in capacitance of the membrane for different level of applied pressure. The capacitance of the deflected membrane is determined by its radial variation of the deflected membrane, which is termed as shape factor. For a given pressure, the shape factor w(r), is related with the peak membrane deflection wₚₖ, the radial distance “r” from the fixed end, and the membrane radius “a”. The shape factor of the membrane deflection is expressed as.

$$w ( r ) = {w}_{pk} ( 1 - ( {r}^{2} / {a}^{2} ) )$$

The shape factor for a given applied pressure gets reflected on the capacitance of the membrane by the expression given below:

$$C = {C}_{0} 1 / √ η arctanh √ n , or C / {C}_{0} = 1 / √ η arctanh √ η$$

where C₀ is the capacitance of the undeflected membrane and η=wₚₖ/tg_{effective}

where tg_{effective}=vacuum gap+ dielectric thickness/its dielectric constant.

FIG. 7 is a graphical representation 7M) that depicts a normalised effective gap of a membrane for special structures in a cavity according to some embodiments herein. In FIG. 4 of the graphical representation 700, atmospheric pressure is plotted on an X-axis and pedestal effective gap normalised to physical gap is plotted on a Y-axis.

In some embodiments, the membrane radius varies from 22 μm to 38 μm in steps of 4 μm. In some embodiments, the membrane thickness of 1.25 μm is selected for operating the CMUT 300 at a higher fundamental resonant frequency. In some embodiments, a physical gap of the membrane including SiO₂ thickness is 0.25 μm, which corresponds to 0.1 μm of an oxide layer and 0.15 μm of vacuum. The effective gap of the membrane cavity due to the presence of the special structure is 0.1777 μm. The incorporation of the special structure in the membrane cavity predicting the collapse voltage as a function of atmospheric pressure is shown in FIG. 7.

The Collapse Voltage for 38-micron and 20-micron radii for different friction radius sizes is shown in below table 3.

In some embodiments results predict a reduction of the effective membrane gap by 40% to 60% for atmospheric pressures in the range of 0.4 atmospheric pressure to 1 atmospheric even at low pressure ranges on the membrane there is a decrease in the effective gap of the membrane by 20%. This is a significant result because the collapse voltage is a square root of the effective membrane gap thereby very low collapse mode operation of CMUT devices is feasible.

The expression for collapse voltage is [1,2]:

$${V}_{collapse} = \sqrt{\frac{8 k {g}_{eff}^{3}}{27 {ε}_{0} {ε}_{r} A}} ( {g}_{eff} - {x}_{dc} )$$

Where k is a spring constant, g_{eff} is the effective gap, z₀ is a dielectric constant of free space. εᵣ is the relative permittivity of the dielectric material inside the cavity, A is the area of the membrane, and (g_{eff}-X_{de}) is the peak deflection of the membrane. In some embodiments, the equation illustrates that the collapse voltage is very sensitive to the effective gap of the membrane. This gap gets considerably reduced by using the special structure in the membrane cavity. Therefore, the collapse voltage will be reduced by using the special structures as described in FIG. 3.

The height of pedestal in the membrane cavity gets virtually fixed by the vacuum gap of the cavity and the final membrane gap being aimed for the CMUT cell. However, the diameter of the pedestal also plays an important role because it facilitates generation of multimode vibrations. The effect of radius of the pedestal on the collapse voltage and it its dependence on the external pressure has been examined for the pedestal with 0.5 times of the cell radius for 38 μm, which demonstrate its effect on higher radii devices more than 50% reduction in the collapse voltage. For comparison purpose, the effect of pedestal size of 0.75 and 0.5 times of the membrane radius of 20 μm is evaluated on the collapse voltage. The effect of using the pedestal in the membrane cavity has more dominant effect on the collapse voltage.

TABLE 4
Dependence of Collapse Voltage on the pressure fraction
of 38 μm and 20 μm radii of pedestal size.

| | Collapse | Collapse | Collapse |
|---|---|---|---|
| Normalized | Voltage for | Voltage for | voltage for |
| Atmospheric | 0.5 times of | 0.75-times of | 0.5 times of |
| pressure | 38 μm radius | 20 μm radius | 20 μm radius |
| 0.1 | 12.33 | 40.758 | 70.14 |
| 0.2 | 11.038 | 34.65 | 66.25 |
| 0.3 | 10.06 | 29.34 | 60.52 |
| 0.4 | 9.105 | 24.8 | 53.85 |
| 0.5 | 8.25 | 20.95 | 47.02 |
| 0.6 | 7.502 | 17.752 | 40.4 |
| 0.7 | 6.825 | 15.08 | 34.4 |
| 0.8 | 6.2328 | 12.875 | 29.2 |
| 0.9 | 5.71 | 11.01 | 24.719 |
| 1 | 5.24 | 9.49 | 20.9 |

FIG. 8 is a graphical representation 800 that depicts the dependence of collapse voltage on the size of a structure according to some embodiments herein. In FIG. 8 of the graphical representation 800, atmospheric pressure is plotted on an X-Axis and collapse voltage is plotted on a Y-Axis. The graphical representation 800 depicts it plot of collapse voltage as a function of the atmospheric pressure in the range of 0.1 μm to 1.0 μm in the steps of 0.1 μm. The fundamental mode of resonant frequency is inversely proportional to the square of the membrane radius. In some embodiments, to cover the entire hand of desired frequencies, the membrane radius is lowered to 22 μm which results in a fundamental resonant frequency of 11.4 MHz In some embodiments, to cover the lower frequency range, a membrane radius of 38 μm is selected for which the membrane resonates at 3.16 MHz. This frequency band is good enough to cover the entire ultrasound imaging range of 1 MHz to 15 MHz after Golay code/Phase Coding implementation.

The gap of the membrane includes a base oxide layer and vacuum gap between the membrane and the oxide layer can be designed to operate the CMUT 300 at a lowered collapse voltage based on a selection of base oxide thickness. The results in FIG. 3 predict that the CMUT devices with moderate radius (28 μm to 38 μm) with the special structure in the cavity can be operated below 40 Volts from 0.2 atmospheric pressure to 0.6 atmospheric. The gap of the cavity, the oxide thickness, and the vacuum between the oxide layer and the membrane can be further optimised in accordance with the shape and size of the special structures in the membrane cavity. The results are compared for the undamped natural frequency which is expressed as:

$$Undamped frequency {ω}_{0} = \sqrt{\frac{k}{m}}$$

Where k is a spring constant of the membrane material and m is the effective mass. Considering the case of <100> silicon this expression for the fundamental undamped modal frequency f₀ gets reduced

$${f}_{0} = 0.3656124 \times {10}^{4} \frac{t}{{r}^{2}}$$

Where t is the membrane thickness and r is the membrane radius.

The results of FIG. 8 for the CMUT 300 are described in FIG. 3, with special structures in the membrane cavity, reduces the IX, voltage below 50 Volts for atmospheric pressure ranging from 0.2 to 0.6 because deep collapse mode occurs at lower de voltages. The CMUT small-signal models can predict more accurately the performance of the CMUT imaging arrays, because operating the CMUT devices at lower dc voltage the spring softening effect can be ignored.

The analysis carried using out COMSOL Simulink 5.5 with MATLAB for different membrane radii and highly doped polysilicon layer is shown in Table 5. The analysis of collapse voltage for different cell radii is also carried out for the structure shown in FIG. 1(a) using COMSOL Multiphysics 5.5 with MATLAB. The results imported are for Impulse response at the operating DX voltage of 40 Volts. The AC response/impulse response has the cumulative effect of DC voltage and AC voltage (which is kept as 1 Volt). The DC voltage, is virtually kept constant at 40 Volts and cell radius, which is primarily the silicon membrane excluding the pillars supporting the membrane and the gap between the polysilicon pedestal and the pillars supporting the silicon membrane are as in FIG. 1(a). The cell radius is varied from 52 μm to 92 μm and pedestal radius which is formed primarily by the highly doped polysilicon is varied from 40 μm to 80 μm.

TABLE 5
Dependence of collapse voltage on the cell diameter for a highly doped polysilicon pedestal diameter.

| DC Voltage ( [symbol] ) | Pedestal | [symbol] | Polysilicon | Cell | | | Silicon | Pedestal | [symbol] Modal | Dominant Modal | [symbol] Modal |
|---|---|---|---|---|---|---|---|---|---|---|---|
| and Atmospheric | Radius | thickness | thickness | radius | Collapse | | Thick [symbol] | membrane | Frequency | Frequency | Frequency |
| Pressure (Pascal) | μm | μm | μm | μm | Voltage | | μm | gap μm | MHz | MHz | MHz |
| 40/ [symbol] | 40 | 0.1 | [symbol] | 52 | 24.5 | V | 2 | 0.3 | [symbol] | [symbol] | [symbol] |
| 40/ [symbol] | 40 | 0.1 | [symbol] | 52 | 24.5 | V | 2 | 0.3 | [symbol] | [symbol] | [symbol] |
| 40/ [symbol] | 40 | 0.1 | [symbol] | 52 | 25 | V | 2 | 0.3 | [symbol] | [symbol] | [symbol] |
| 0/ [symbol] | 40 | 0.1 | [symbol] | 52 | [symbol] | | 2 | 0.3 | [symbol] | [symbol] | [symbol] |
| 40/ [symbol] | 40 | 0.1 | [symbol] | 52 | 25 | V | 2 | 0.3 | [symbol] | [symbol] | [symbol] |
| 40/ [symbol] | 40 | 0.1 | [symbol] | 52 | 24 | V | [symbol] | 0.2 | [symbol] | [symbol] | [symbol] |
| 40/ [symbol] | 52 | 0.1 | [symbol] | 62 | 24.5 | V | 2 | 0.3 | [symbol] | [symbol] | [symbol] |
| 40/ [symbol] | 60 | 0.1 | [symbol] | 72 | 25 | V | 2 | 3 | [symbol] | [symbol] | [symbol] |
| 40/ [symbol] | 70 | 0.1 | [symbol] | 80 | 15 | V | 2 | 3 | [symbol] | [symbol] | [symbol] |
| 40/ [symbol] | 80 | 0.1 | [symbol] | [symbol] | 12.5 to 15 | V | 2 | 3 | [symbol] | [symbol] | [symbol] |

[symbol]

indicates data missing or illegible when filed

The collapse voltage for smaller cell radius of 52 μm to 80 μm is typically 24,5 Volts. Whereas, for larger radius above 80 μm the effect of atmosphere pressure further reduces the collapse voltage to 15 Volts. An additional feature observed in the impulse response of the frequency spectrum had been the dominance of response at 18,836 MHz (typically intensity of the peak above 2.78×10\hat{ }7 Pascal) and a sub peak at 14.15 MHz (0.75×10\hat{ }5), as magnitude lower than the dominant peak in the desired ultrasonic bandwidth. A higher mode ranging in the frequency band of 21 to 31 MHz has also been observed. However, a dominant frequency mode of 2.985 MHz (0.485×10\hat{ }5) and at frequency of 14.125 MHz it is 0.2575×10\hat{ }4 Pascal. For the collapse voltage of 40 Volts for the polysilicon radius of 38 μm the dominant peak is at 2.371 MHz with an intensity of 1.04×10\hat{ }5 Pascal,

The important parameters on the design of a CMUT cell are the range resolution, sensitivity and its ease of implementation of spread spectrum in the transmission and receiver mode of operation of the CMUT cell. Higher is the resonant/modal frequency of operation of the CMUT ell better is the range resolution. The dominant frequency for the structures in FIG. 1, 2 is 18.836 MHz which provides the range resolution 81.75 μm and facilitates radiation of more power by putting up to 5 wavelengths in each bit while implementing the Golay/phase coding scheme. The range resolution can be further enhanced by spreading the spectrum in the transmission mode and compressing it in the receiver mode of operation.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

I/We claim:

1. A method for designing a low voltage capacitive micromachined ultrasonic transducer (CMUT), comprising steps of;
starring from a base silicon wafer 1202) comprises starting with a N-type Silicon Wafer and growing base oxide by performing the following steps:
(i) patterning with a metal mask over the base oxide;
(iii patterning with a Field Oxide (FOX) Mask over a copper (Cu) or aluminium (Al) metal (M1) layer that is deposited over the base oxide; and
(iii) depositing polysilicon (208) over the entire silicon wafer (202) and doping the polysilicon (208) with a donor species with a concentration approaching its respective solid solubility limit, subsequently depositing titanium (Ti) (210) over the doped polysilicon that is deposited on the entire silicon wafer (202), and subsequently depositing a dielectric layer, wherein the dielectric layer is standalone Silicon Dioxide or in a stack with Hafnium Oxide or alternatively in a stack with Silicon Nitride or a stack of high relative permittivity materials:
(iv) patterning with a pedestal-poly mask over a dielectric layer that is deposited over the titanium (210);
(v) removing the patterned dielectric by a wet etch process and subsequently removing exposed titanium by an alternative wet etch process and sequentially excavating by reactive ion etch (RIE) all exposed polysilicon; and
(vi) planarizing surface of the base silicon wafer by chemical mechanical polishing (CMP), thereby preparing the base silicon wafer (202) for eventual bonding with a separate top silicon wafer; and
starting with the separate top silicon wafer comprising a silicon “device” layer on top of buried oxide grown over a thick “handle” silicon layer and performing the following steps:
(vii) depositing by sputtering an aluminium layer, wherein the aluminium layer is Metal 2 (220); and
(viii) patterning with a Metal 2 Mask and etching the Metal 2 (220) by a wet etch process;
(ix) patterning with a CMUT Cell mask and etching the silicon “device” layer by RIE to define a CMUT top plate;
(x) aligning the separate top silicon wafer and the base silicon wafer to enable the Metal 2 (220) of the separate top silicon wafer to align with Pillar Poly of the base silicon wafer; and heating the separate top silicon wafer and the base silicon wafer after the separate top silicon wafer and the base silicon wafer are aligned to enable the Metal 2 (220) of the separate top silicon wafer to align with Pillar Poly of the base silicon wafer, and to (a) form a eutectic bonding between the polysilicon (208) and aluminium during which a certain thickness of the Metal 2 (220) is consumed, and (b) form a Polycide between the Polysilicon (208) and the Titanium (Ti (210) alloy in parallel, wherein the Titanium (210) present inside the cavity (i) acts as a getter when the eutectic bonding is happening between the polysilicon (208) and aluminium, (ii) forms chemical bonds with residual Nitrogen and Oxygen, and (c) removes the residual Nitrogen and Oxygen from the cavity, thereby improving vacuum in the cavity;
(xi) depositing a Polymer layer (222) over an entire wafer; and
(xii) patterning with a Polymer Mask and selectively etching the Polymer (222) to
(a) isolate CMUT cells from mechanical coupling and (b) remove the polymer (222) at bond pads.

2. The method as claimed in claim 1 wherein the N-Type Silicon Wafer is replaced by P-Type Silicon Wafer, wherein concentration of the N-type Silicon Wafer is 5×10¹⁵/cm³, wherein the base oxide has 0.5 μm thickness.

3. The method as claimed in claim 1, wherein the method comprises performing dry oxidation of a silicon wafer to obtain a required silicon dioxide (SiO2) thickness of the base silicon wafer, the dry oxidation is performed at 1050° C. for an appropriate time, wherein the required oxide thickness is 1 μm; and
depositing the copper (Cu) or aluminium (Al) metal (M1) layer with a required thickness over the base oxide (SiO2), wherein a thickness of the copper or Al metal 1 layer is based on a design specification of resistivity.

4. The method as claimed in claim 1, wherein the method comprises etching the copper/Al metal using a wet etch process to create a CMUT bottom plate and a metal (M1) interconnect layer after the metal mask is patterned over the base oxide; and depositing conformally SiO2 using Plasma-Enhanced Chemical Vapor Deposition (PECVD) over an entire silicon wafer.

5. The method as claimed in claim 1, wherein the method comprises etching the PECVD SiO2 after the Field Oxide (FOX) Mask is patterned using buffer Hydrogen Fluoride (HF) solution to obtain CMUT cavities.

6. The method as claimed in claim 1, wherein the method comprises etching the dielectric layer using the wet etch process to expose the titanium from all areas where underlying poly is to be etched, wherein the dielectric layer is at least one of SiO2, SiO2/HfO2 sandwich or SiO2/Si3N4 sandwich.

8. The method as claimed in claim 1, wherein the method comprises etching the Titanium (210) by the wet-etch process where the polysilicon (208) acts as an “etch-stop”, wherein the Titanium (Ti) (210) is deposited over the polysilicon (208) with a thickness of 100 nm by sputtering.

9. The method as claimed in claim 1, wherein the method comprises excavating the polysilicon (208) inside cavity around the pedestal and in regions adjacent to pillars to prevent shorting of adjacent CMUTs.

10. The method as claimed in claim 1, wherein the Chemical Mechanical Polishing (CMP) is performed on the polysilicon (208) with a thickness of 1.4 μm to remove the excess dielectric on the pillar; and the titanium (Ti) (210) on pillar polysilicon and the excess height of the polysilicon (208) to render the surface of a wafer planar.

11. The method as claimed in claim 1, wherein the method comprises chemical mechanical polishing (CMP) of the handle silicon layer by RIE and, sequentially, a buried oxide layer by the wet etch process.

12. The method as claimed in claim 1, wherein the separate top silicon wafer comprises a heavily doped top n+ silicon layer that is intended to be a membrane with a thickness of 2 μm, wherein the separate top silicon wafer comprises the thick handle silicon layer that is removed by RIE and the buried oxide layer placed below with the thickness of 0.5 μm which is removed by the wet-etch process with the silicon device layer acting as etch-stop for its removal.

13. The method as claimed in claim 1, wherein the Metal 2 (220) of thickness 0.8 μm is reduced to 0.4 μm during eutectic bonding at 600° C. and a 0.1 μm thick membrane dielectric leaves a gap of 0.3 μm, wherein different combinations of the Metal 2 (220) thickness and membrane dielectric thickness are used to control gap between the membrane and the pedestal and different sandwich stacks to simultaneously achieve a desired capacitance value of the CMUT independent of the gap thickness.

14. The method as claimed in claim 1, wherein two plates of the CMUT embodied as the Metal 1 (206) and the Metal 2 (220) are isolated from corresponding plates of other CMUT cells on a same die, this isolation enabling compensation of stray capacitances by suitable circuit techniques.

15. The method as claimed in claim 1 wherein a pedestal in one or more sizes and one or more shapes comprising interleaved and grid-like structures is constructed inside the cavity of the CMUT, wherein the pedestals enable lowering of the collapse voltage, enable lowering of operating voltages and improve control on a resonant frequency sf vibration of the membrane.

16. The method as claimed in claim 1 wherein a dielectric is instead deposited inside the cavity on the underside of the membrane on the top wafer by suitable modification of process steps.
